(19) United States
(12) Patent Application Publication
(10) Pub. No.: US 2006/0284115 A1
(43) Pub. Date: Dec. 21, 2006

(54) Ion beam apparatus and analysis method

(76) Inventors: Noriyuki Kaneoka, Hitachinaka (JP); Kaoru Umemura, Hitachinaka (JP); Koji Ishiguro, Hitachinaka (JP); Hiroyasu Shichi, Tokyo (JP); Satoshi Tomimatsu, Kokubunji (JP)

Correspondence Address: MCDERMOTT WILL & EMERY LLP, 600 13TH STREET, N.W., WASHINGTON, DC, 20005-3096, US

(21) Appl. No.: 11/439,541

(22) Filed: May 24, 2006

(30) Foreign Application Priority Data
May 26, 2005 (JP) 2005-153660

(51) Int. Cl. H01J 37/08

(52) U.S. Cl. 250/492.21

(57) ABSTRACT

A technique is provided which can precisely form a deposition pile in a hole bored in the surface of a specimen. In ion beam apparatus and analysis method, the specimen surface is bored or a deposition pile is formed in the hole bored in the specimen surface. A measuring instrument is provided for measuring a height of the hole bored in the specimen surface or a height of the deposition pile formed in the hole. During fabrication of boring the hole in the specimen surface or fabrication of filling the hole bored in the specimen surface, an image of an area encompassing the hole and the depth of the hole or the height of the deposition pile are displayed.

### BACKGROUND OF THE INVENTION

The present invention relates to an apparatus for ion beam fabrication and observation used in a process for inspection of a semiconductor device and more particularly, to an ion beam apparatus adapted to bore a hole for observation and form or deposit a deposition pile used to fill the hole and an ion beam analysis method.

In manufacturing semiconductor devices such as microprocessors or memories, reducing the number of defective devices and obtaining a high yield are required. This leads to significant issues in assuring early finding of defects such as defective continuity or short-circuit and foreign matters responsible for degradation of the yield and early countermeasures as well.

In order to detect defective devices, it has hitherto been practice to conduct an electrical inspection with, for example, an LSI tester using a probe in the phase of completion of the function of devices. Today, however, an inspection has been conducted midway in a process to aim at early detection and early taking of countermeasures. In such a case, a semiconductor device is returned to the manufacture process after completion of its inspection.

To analyze causes of a defect, a sectional geometry of a portion determined as being defective through inspection is observed. In preparation for the observation of the sectional geometry, a cross section is created by irradiating an ion beam on a specimen such as a wafer to cut off or shave the surface of the specimen on the basis of a sputtering phenomenon. This cross section is observed with a scanning electron microscope (SEM) to analyze causes of the defect.

However, as the degree of integration of a semiconductor device and minuteness of the process advances, the resolution of the normal SEM is not enough to observe the cross section of a specimen.

To cope with this problem, a method is available in which a part of a specimen is cut off through fabrication using an ion beam and the cut-off piece of specimen is observed and analyzed by using an SEM or transmission electron microscope having high resolution.

In the method of sectioning the specimen surface or partly cutting off the specimen, a hole is bored in the specimen. When the specimen with the remaining hole is returned to a semiconductor manufacture process, there is a possibility that the specimen will be recognized as a defective device. Under the circumstances, a method is employed according to which the hole is filled with a deposition pile and thereafter a resultant specimen is returned to the semiconductor manufacture process. As an example to this effect, one may refer to JP-A-2003-311435 entitled “A hole filling method based on an ion beam, an ion beam fabrication and observation apparatus and a method for manufacture of electronic parts”.

### SUMMARY OF THE INVENTION

In the prior art, the thickness or height of a deposition pile for filling a hole cannot be controlled precisely, with the result that the peripheral edge of the hole cannot be flush with the deposition pile filling the hole, forming an uneven site in the surface of a semiconductor device. For example, in case the thickness of a deposition pile is small, a hole cannot be filled thoroughly to form a concave site whereas in the event that the thickness of a deposition pile is large, a deposition pile filling a hole results in a convex site.

In a general semiconductor process, if a concave or convex site having a depth or height of 50 nm or more is present on the surface of a semiconductor device, the convex site is cut off or shaved through CMP (chemical mechanical polishing) process. Disadvantageously, a cut-off piece of specimen causes the specimen to be scratched or gives rise to non-uniformity of coating of a resist agent applied by means of a spin coater in a photo-resist process.

An object of this invention is to provide a technique capable of precisely forming a deposition pile in a hole bored in the specimen surface.

According to the present invention, in an ion beam apparatus adapted to bore a hole in the surface of a specimen or form a deposition pile in the hole bored in the specimen surface, a measuring instrument is provided which measures the depth of the hole bored in the specimen surface or the height of the deposition pile filled in the hole.

During fabrication of boring a hole in the specimen surface or fabrication of filling the hole bored in the specimen surface, an image of an area encompassing the hole and the depth of the hole or the height of a deposition pile are displayed.

The measuring instrument includes a laser beam source for emitting or irradiating a laser beam into a hole or onto a deposition pile and a laser beam detector for detecting a laser beam from an irradiation area. The measuring instrument may be a scanning electron microscope.

According to the present invention, a deposition pile can be formed precisely in a hole bored in the specimen surface.

Other objects, features and advantages of the invention will become apparent from the following description of the embodiments of the invention taken in conjunction with the accompanying drawings.

### BRIEF DESCRIPTION OF THE DRAWINGS

FIG. 1 is a schematic diagram showing a first embodiment of ion beam apparatus and analysis method according to the present invention.

FIGS. 2A to 2C are diagrams useful to explain a method of measuring the height of a deposition pile according to the invention.

FIG. 3 is a diagram showing an operation screen during hole boring.

FIG. 4 is a diagram showing an operation screen during hole filling.

FIG. 5 is a flowchart of a hole filling process.

FIGS. 6A to 6C are diagrams showing a second embodiment of the ion beam apparatus and analysis method according to the invention.

FIG. 7 is a diagram showing an operation screen during hole filling.

FIG. 8 is a flowchart of a hole filling process.

FIGS. 9A and 9B are diagrams showing a third embodiment of the ion beam apparatus and analysis method according to the invention.

FIG. 10 is a diagram showing a fourth embodiment of the ion beam apparatus and analysis method according to the invention.

FIG. 11 is a diagram showing an operation screen during hole boring.

FIG. 12 is a diagram showing an operation screen during SEM image observation.

FIG. 13 is a diagram showing an operation screen during hole filling.

FIG. 14 is a diagram showing a fifth embodiment of the ion beam apparatus and analysis method according the invention.

### DETAILED DESCRIPTION OF THE EMBODIMENTS

The present invention will now be described by way of example with reference to the accompanying drawings.

### Embodiment 1

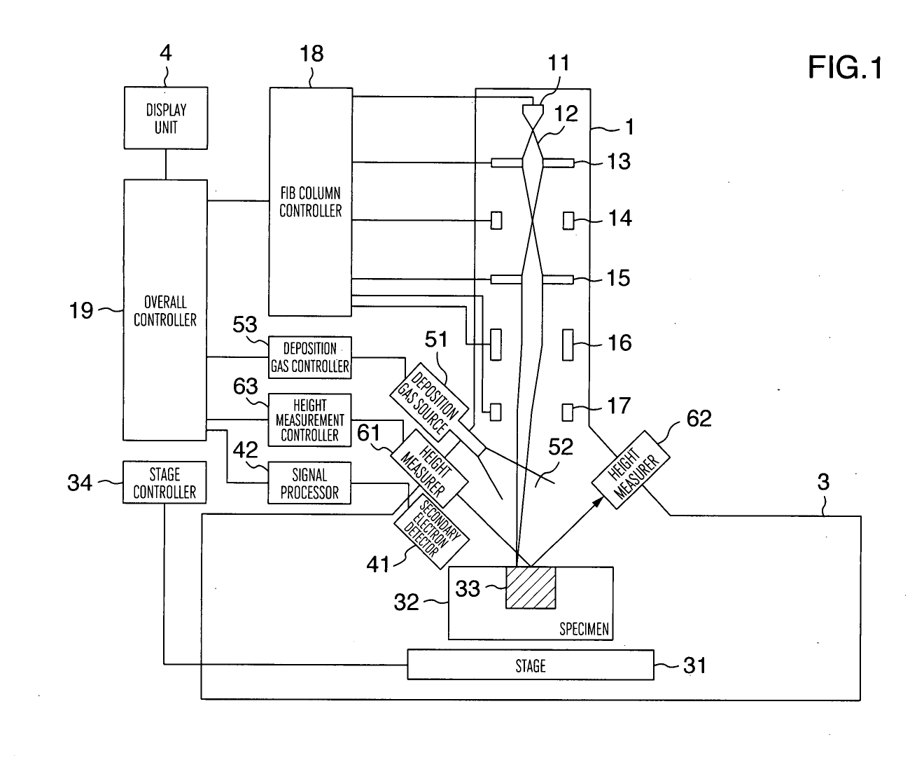

Referring first to FIG. 1, there is illustrated a first embodiment of ion beam apparatus and analysis method according to the invention. The ion beam apparatus of the present embodiment comprises an FIB column 1 provided for a specimen chamber 3. The FIB column 1 includes an ion source 11, an extraction electrode 13, a condenser lens 14, an aperture 15, a deflector 16 and an objective lens 17, having its interior maintained at high vacuum. The specimen chamber 3 is provided with a stage 31, a secondary electron detector 41, a deposition gas source 51, a height measurer (on laser beam source side) 61 and a height measurer (on laser beam detector side) 62.

The ion beam apparatus further comprises an FIB column controller 18, an overall controller 19, a stage controller 34, a deposition gas controller 53, a height measurement controller 63, a signal processor 42 and a display unit 4.

The FIB column controller 18 controls voltages applied to the ion source 11, extraction electrode 13, condenser lens 14, aperture 15, deflector 16 and objective lens 17.

The stage controller 34 controls the stage 31 adapted to hold a specimen 32 such as a wafer so as to move the stage 31 in three-dimensional direction and in rotary direction.

The deposition gas controller 53 controls start and stop of the supply of a deposition gas 52 confined in the deposition gas source 51. Used as the deposition gas 52 is, for example, W(CO)₆. The height measurement controller 63 controls the height measurer (on laser beam source side) 61 and height measurer (on laser beam detector side) 62. The height measurer 61 has a laser beam source to emit or irradiate a laser beam onto a measuring position on the specimen 32. The height measurer 62 has an element, such as for example a photodiode, for detecting a laser beam and converting it into an electrical signal. Operation of the height measurers 61 and 62 will be described later.

The ion source 11 contains a liquid metal such as Ga. When a high voltage is applied to the ion source 11 and a voltage lower than the high voltage applied to the ion source 11 is applied to the extraction electrode 13, an ion beam 12 is emitted from the ion source 11. The ion beam 12 is focused by the condenser lens 14, so that the amount of ion beam passing through the aperture 15 can be adjusted. The ion beam 12 having passed through the aperture 15 is deflected by the deflector 16 and focused by means of the objective lens 17. The focused ion beam 12 is scanned on the specimen 32.

Under irradiation of the ion beam 12 on the specimen 32, constituent atoms in the surface of specimen 32 are discharged through a sputtering phenomenon. As a result, the surface of specimen 32 is cut off or shaved, boring a hole. The hole is bored such that a sectional geometry of specimen 32 can be observed, that is, a cross section of specimen 32 is exposed on the inner wall of the hole. With the hole bored, the cross section of specimen 32 can be observed by tilting the stage 31.

When the ion beam 12 is irradiated while supplying the deposition gas 52, the composition of the deposition gas is changed so that a deposition pile 33 of W (tungsten) may be formed on the specimen 32. Normally, the deposition pile is used to protect the specimen surface at the peripheral edge of a hole for cross section observation or to correct or modify wiring but in the present invention, it is used to fill the hole for cross section observation as will be described hereinafter.

The secondary electron detector 41 detects secondary electrons generated from the specimen 32 irradiated with the ion beam 12. The signal processor 42 processes a secondary electron detection signal from the secondary electron detector 41 in synchronism with a scanning signal for beam deflection and outputs a resultant signal to the overall controller 19. The overall controller 19 displays an SIM (scanning ion beam microscope) image on the screen of display unit 4.

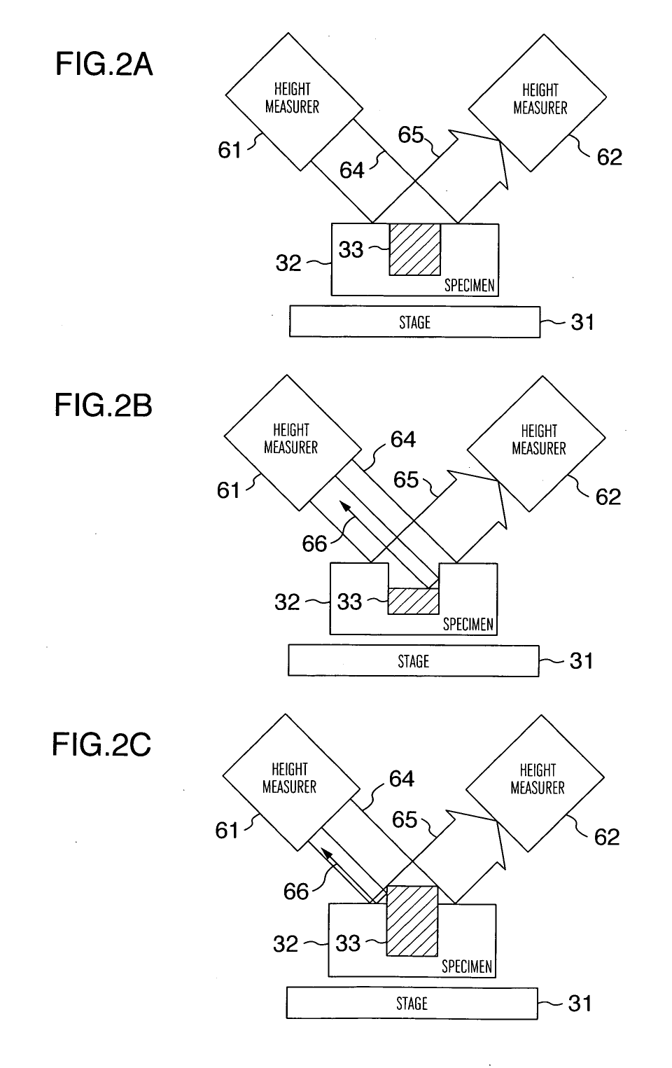

Turning to FIGS. 2A to 2C, a method of measuring a hole bored in the specimen and the height of a deposition pile will be described. Illustrated in FIG. 2A is an instance where the height of the peripheral edge of a hole coincides with the height of a deposition pile 33 filled in the hole. The height measurer (on laser beam source side) 61 irradiates a laser beam 64 onto an area on specimen 32 in which the deposition pile 33 has been formed. The laser beam 64 emitted from the height measurer 61 has a beam spot sized enough to cover the hole. The height measurer (on laser beam detector side) 62 detects a laser beam 65 from the laser irradiation area. In this example, the laser irradiation area is flat. Consequently, the height measurer 62 detects the maximum level of laser beam 65 from the laser irradiation area.

Illustrated in FIG. 2B is an instance where the height of a filled deposition pile 33 is lower than the height of the peripheral edge of a hole. In this example, a recess is formed having its bottom defined by the deposition pile 33. In other words, the laser irradiation area is not flat. The height measurer 61 emits a laser beam 64 to an area of specimen 32 in which the deposition pile 33 is formed. Part of the laser beam 64 is irradiated on the peripheral edge of the hole but most of the laser beam 64 is irradiated on the recess formed by the deposition pile 33. As shown, the laser beam 64 irradiated on the recess behaves as a scatter beam 66 which is not directed to the height measurer 62. The scatter beam 66 is partly directed to the height measurer 61. As a result, the quantity of laser beam detected by the height measurer 62 is less than that indicated in FIG. 2A.

Illustrated in FIG. 2C is an instance where the height of a filled deposition pile 33 is higher than the height of the peripheral edge of a hole. In this example, a raised site is formed by the deposition pile 33. In other words, the irradiation area is not flat. The height measurer 61 emits a laser beam 64 to an area of specimen 32 in which the deposition pile 33 is formed. Part of the laser beam 64 is irradiated on the peripheral edge of the hole but most of the laser beam 64 is irradiated on the raised site formed by the deposition pile 33. As shown, the laser beam 64 irradiated on the raised site behaves as a scatter beam 66 which is not directed to the height measurer 62. Part of the scatter beam 66 is directed to the height measurer 61. Consequently, the quantity of laser beam detected by the height measurer 62 is also less than that in the case of FIG. 2A.

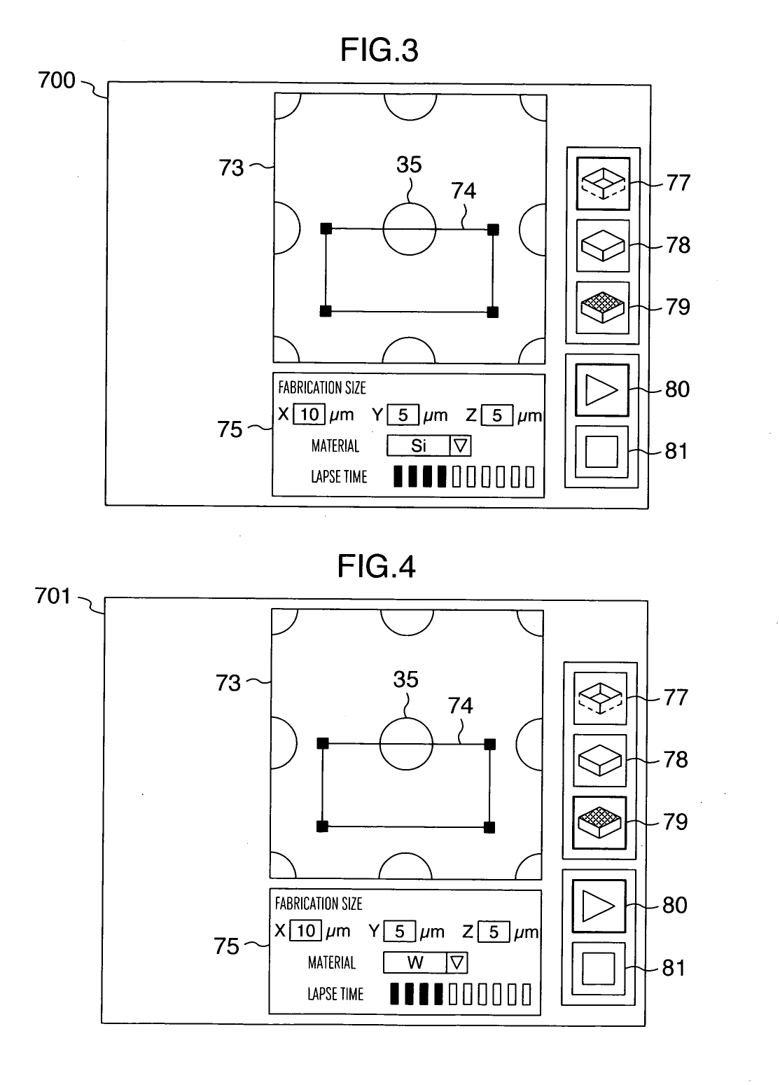

An operation screen 700 displayed on the display unit 4 during hole boring fabrication will be described with reference to FIG. 3. The operation screen 700 includes an image display area 73, a condition display area 75, a hole boring button 77, a deposition pile forming button 78, a hole filling button 79, a start button 80 and a stop button 81. By clicking the hole boring button 77, an SIM image of specimen 32 around a hole boring area and a rubber band 74 designating the hole boring area are displayed in the image display area 73. Circular contact holes 35 have already been formed in the specimen surface. The rubber band 74 is so set as to form a cross section of a contact hole 35. When the start button 80 is clicked, an ion beam 12 is irradiated on an area defined by rubber band 74 on the surface of specimen 32 and a hole boring fabrication is started. Indicated in the condition display area 75 are a fabrication size, a material of the specimen and a lapse time. The fabrication size represents a geometrical dimension of the hole.

Turning to FIG. 4, an operation screen 701 displayed on the display unit 4 during hole filling fabrication will be described. By clicking the hole filling button 79, an SIM image around the hole and a rubber band 74 designating a hole filling area are displayed on the image display area 73. A rectangular hole for exposing a cross section of a contact hole has already been formed in the specimen surface. When the hole filling button 79 is clicked, the rubber band 74 is displayed in register with the rectangular hole according to standards. Through drag operation of a mouse, for example, the position of rubber band 74 can be changed. With the start button 80 clicked, a deposition gas is supplied from the deposition gas source 51 and a deposition pile is formed in the area defined by the rubber band 74. In this manner, the hole is filled with the deposition pile. In place of the hole filling button 79, the deposition pile forming button 78 may be clicked. In this case, the area to be defined by the rubber band 74 is set through, for example, drag operation of a mouse.

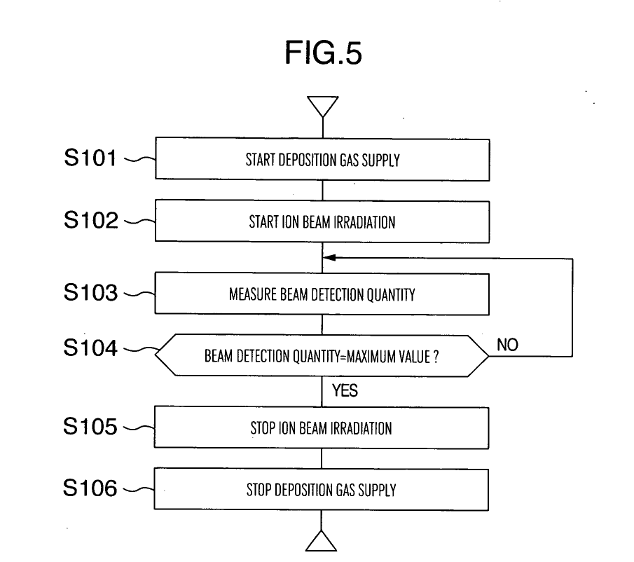

A process of hole filling fabrication will be described with reference to FIG. 5. In step S101, supply of deposition gas 52 is started. In step S102, irradiation of ion beam 12 is started. In step S103, the height measurer 61 irradiates a laser beam onto a hole filling area and the height measurer 62 detects a beam from the irradiation area, thereby measuring a quantity of detected beam. In step S104, it is decided whether the detected beam quantity is maximized. As the detected beam quantity becomes maximal, the irradiation of ion beam 12 is stopped in step S105. In step S106, the supply of deposition gas is stopped to end the hole filling fabrication.

In this example, the hole filling proceeds while the height of the deposition pile being measured. In other words, the height of the deposition pile is measured and on the basis of a result of the height measurement, formation of the deposition pile is stopped. For example, at the time that the height of the deposition pile substantially equals the height of the peripheral edge of the hole, formation of the deposition pile is stopped. Alternatively, when the unevenness of specimen surface comes to 50 nm or less, formation of the deposition pile is stopped. In this manner, the filled deposition pile can be substantially flush with the hole. Alternatively, the unevenness of specimen surface can be 50 nm or less. Accordingly, even a wafer having gone through the hole filling with the deposition pile is returned to the process line, a problem of generation of a defective device can be avoided. In addition, the wafer need not be discarded and an economical advantage can be attained.

### Embodiment 2

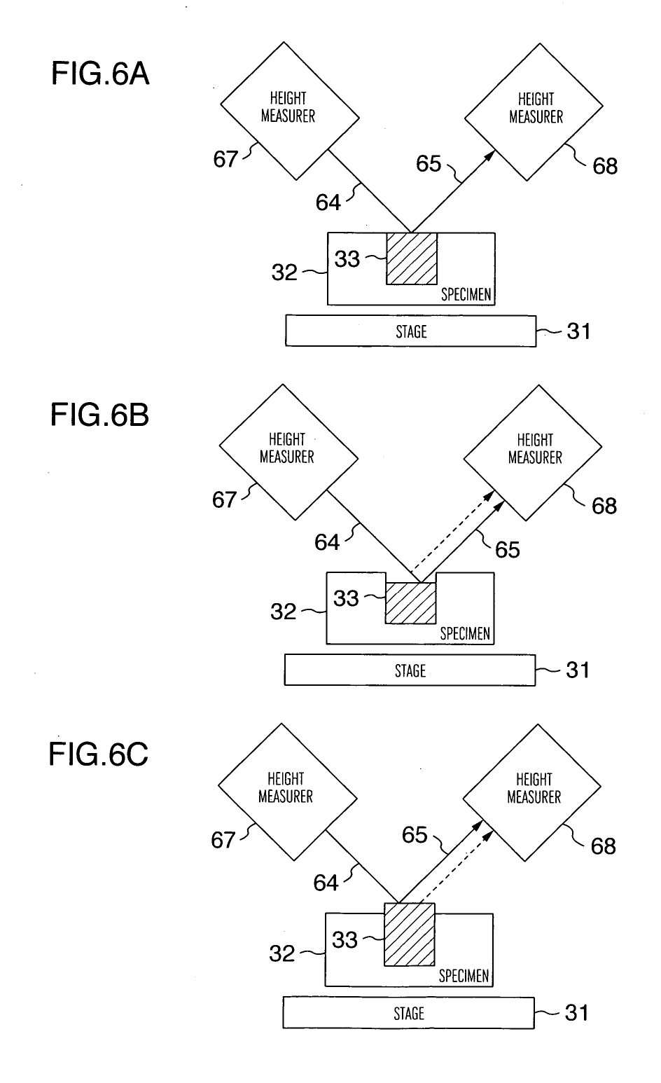

Referring to FIGS. 6A to 6C, a second embodiment of the ion beam apparatus and analysis method according to the invention will be described. The ion beam apparatus of the present embodiment is identical to that of the first embodiment shown in FIG. 1 with the only exception that the height measurer (on laser beam source side) and the height measurer (on laser beam detector side) are different from those in FIG. 1. Accordingly, in FIGS. 6A to 6C, only height measurer (on laser beam source side) 67 and height measurer (on laser beam detector side) 68 are illustrated.

In the present embodiment, the height measurer 67 emits a laser beam 64 having a beam spot smaller than a diameter of hole. In the height measurer 68, a CCD (charge coupled device), for example, is used to detect positions of detection of a laser beam 65. When the position of emission of the laser beam from the height measurer 67 is fixed, the position of incidence of the laser beam on the height measurer 68, that is, the beam detection position of the measurer changes with the height of a laser beam irradiation area. Accordingly, on the basis of the position at which the height measurer 68 detects the laser beam, the height of the deposition pile can be measured.

Illustrated in FIG. 6A is an instance where the height of the peripheral edge of a hole coincides with the height of a hole filling deposition pile 33. The height measurer 67 emits onto the deposition pile 33 on specimen 32 a laser beam 64 having a beam spot smaller than a diameter of the hole. The height measurer 68 detects a laser beam 65 from a laser irradiation area and memorizes an incident position. In this example, the laser irradiation area is flush with the peripheral edge of the hole. Accordingly, the beam detection position detected by the height measurer 68 is set as a reference position.

Illustrated in FIG. 6B is an instance where the height of a deposition pile 33 filling a hole is lower than the height of the peripheral edge of the hole. In this example, the deposition pile 33 defines a recess. The height measurer 67 irradiates a laser beam 64 onto the deposition pile 33 on specimen 32. The height measure 68 detects a laser beam 65 from a laser irradiation area and memorizes beam detection positions. In this example, the height of the laser irradiation area is lower than the height of the peripheral edge of the hole. Accordingly, the beam detection position detected by the height measurer 68 deviates from the reference position. In accordance of an amount of deviation, a depth of the recess the deposition pile 33 defines can be measured.

Illustrated in FIG. 6C is an instance where the height of a deposition pile 33 filling a hole is higher than the height of the peripheral edge of the hole. In this example, a raised site is formed by the deposition pile 33. The height measurer 67 irradiates a laser beam 64 onto the deposition pile 33 on specimen 32. The height measurer 68 detects a laser beam 65 from a laser irradiation area and memorizes beam detection positions. In this example, the height of the laser irradiation area is higher than the height of the peripheral edge of the hole. Accordingly, the beam detection position detected by the height measurer 68 also deviates from the reference position. In accordance with an amount of deviation, a height of the raised site the deposition pile 33 defines can be measured.

In the present embodiment, by using the laser beam 64 of a reduced beam spot, the height of the recess or raised site can be measured locally. Accordingly, this makes it possible to fill up a recess partially or locally formed in a deposition pile 33 which is lower than the peripheral edge of a hole and to remove a raised site partially or locally formed on a deposition pile which is higher than the peripheral edge of a hole.

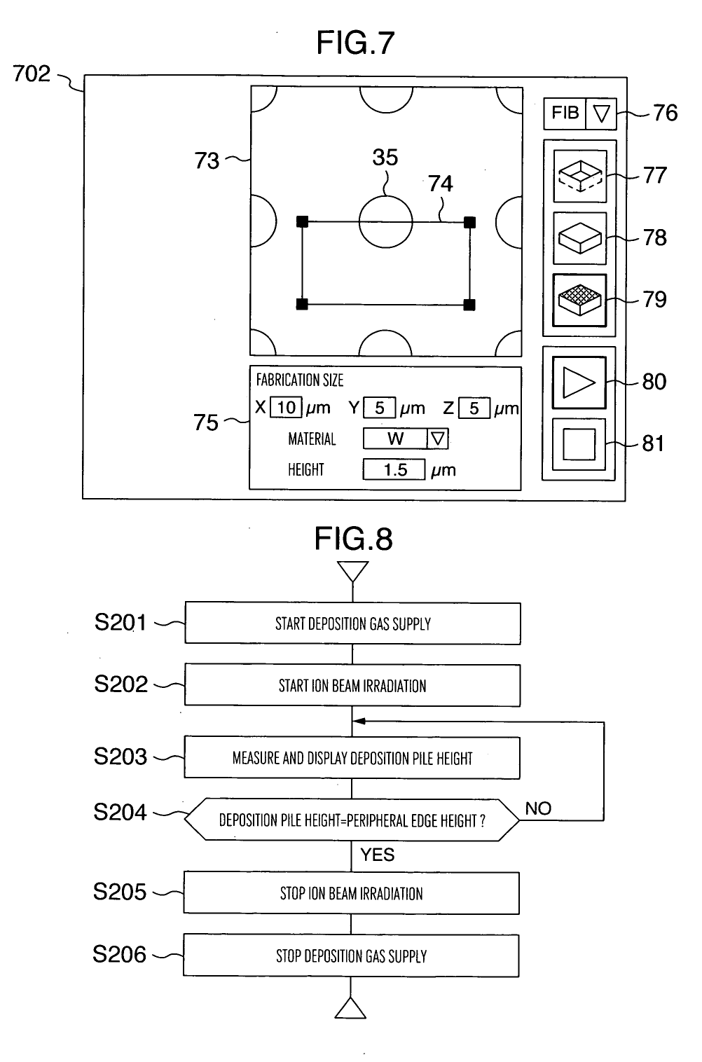

Reference is now made to FIG. 7 to explain an operation screen 702 displayed on the display unit 4 during hole filling fabrication. The operation screen 702 in this example is substantially identical to the operation screen 701 of FIG. 4 with the only exception that a fabrication size, a specimen material and a height are indicated in a condition display area 75 of operation screen 702. The fabrication size represents a geometrical dimension of the deposition pile and the height represent a height the deposition pile exhibits at present. When the deposition pile becomes flush with the peripheral edge of the hole, the hole filling fabrication ends.

A process of hole filling fabrication will be described with reference to FIG. 8. In step S201, supply of a deposition gas 52 is started. In step S202, irradiation of an ion beam 12 is started. In step S203, the height measurer 67 irradiates a laser beam onto a hole filling area. Then, the height measurer 68 detects a beam from an irradiation area and measures a depth of a hole, that is, a height of a deposition pile from a beam detection position to display a measurement result. In step S204, it is decided whether the height of the deposition pile substantially equals the height of the peripheral edge position of the hole. If the deposition pile becomes substantially flush with the hole peripheral edge position, the irradiation of ion beam 12 is stopped in step S205. In step S206, the supply of the deposition gas is stopped and the hole filling fabrication ends.

In the present example, the hole filling proceeds meanwhile the height of the deposition pile being measured. In other words, the height of the deposition pile is measured and on the basis of a measurement result, formation of the deposition pile is stopped. At the time that the height of the deposition pile substantially equals the height of the peripheral edge of the hole, the formation of the deposition pile is stopped. Alternatively, when the unevenness on the specimen surface comes to 50 nm or less, the formation of the deposition pile is stopped. In this manner, the deposition pile filling the hole can be substantially flush with the peripheral edge of the hole. Alternatively, the unevenness on the specimen surface can be 50 nm or less. Accordingly, even the wafer undergoing hole filling with the deposition pile is returned to the process line, a problem of generation of a defective device can be avoided. In addition, the wafer need not be discarded, having an economical advantage.

### Embodiment 3

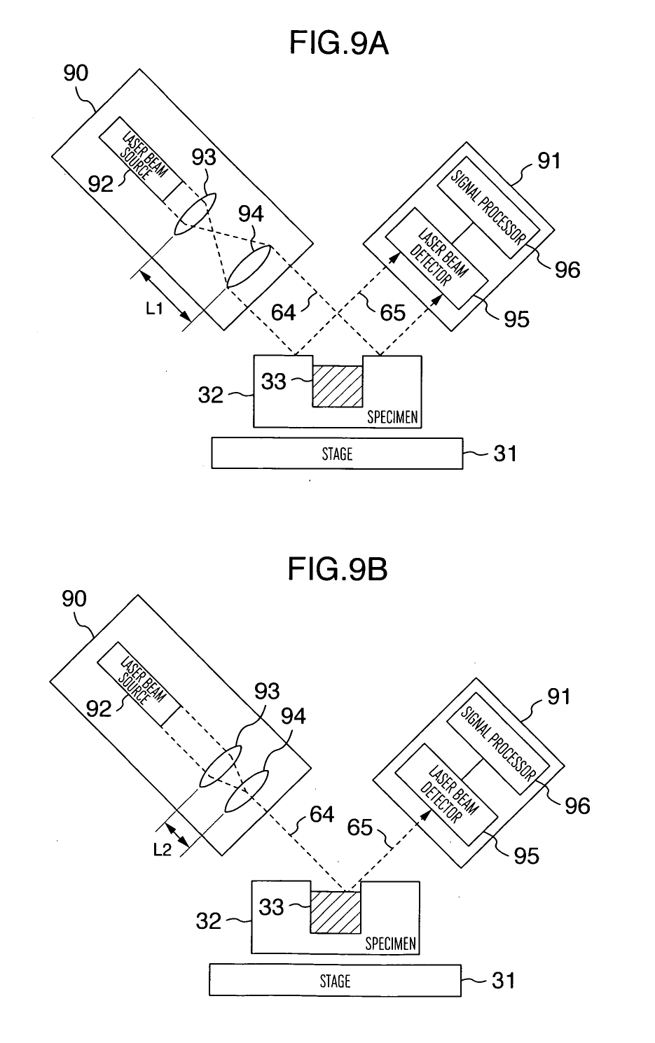

Turning now to FIGS. 9A and 9B, a third embodiment of the ion beam apparatus and analysis method according to the invention will be described. The ion beam apparatus of the present embodiment is identical to the first embodiment of FIG. 1 with only exception that the height measurer (on laser beam source side) and the height measurer (on laser beam detector side) differ from those of FIG. 1. Accordingly, only height measurer (on laser beam source side) 90 and height measurer (on laser beam detector side) 91 are particularly illustrated in FIGS. 9A and 9B.

In the present embodiment, the height measurer 90 includes a laser beam source 92 such as a semiconductor laser, a lens 93 and a lens 94. The height measurer 91 includes a laser beam detector 95 such as a CCD adapted to detect the intensity of the laser beam two-dimensionally and a signal processor 96. The height measurer 90 can change the beam spot of a laser beam 64 by changing distance L between the two lenses 93 and 94. The height measurer 91 measures both the quantity of detected laser beam and the beam detection position.

Illustrated in FIG. 9A is an instance where the distance L between lenses 93 and 94 is L1 and the height measurer 90 emits a laser beam 64 having a relatively large beam spot. This corresponds to the case shown in FIGS. 2A to 2C. On the basis of a quantity of a laser beam the laser beam detector 95 detects, the signal processor 96 decides whether the height of a deposition pile 33 is higher or lower than or equal to the height of the peripheral edge and besides, measures a height of the deposition pile 33. In the present example, by determining a position of the center of gravity the detection beam signals have, the signal processor 96 may measure an average height of an area irradiated with the beam.

Illustrated in FIG. 9B is an instance where the distance L between lenses 93 and 94 is L2 and the height measurer 90 emits a laser beam 64 having a relatively small beam spot. This corresponds to the case shown in FIGS. 6A to 6C. On the basis of a position at which a laser beam is detected by the laser beam detector 95, the signal processor 96 decides whether a height of a deposition pile 33 is higher or lower than or equal to a height of the peripheral edge and besides measures a height of the deposition pile 33. In the present example, by determining a position of the center of gravity the detection beam positions have and that the detection beam signals have, the signal processor 96 can measure a height of the deposition pile 33 in the area irradiated with the beam.

### Embodiment 4

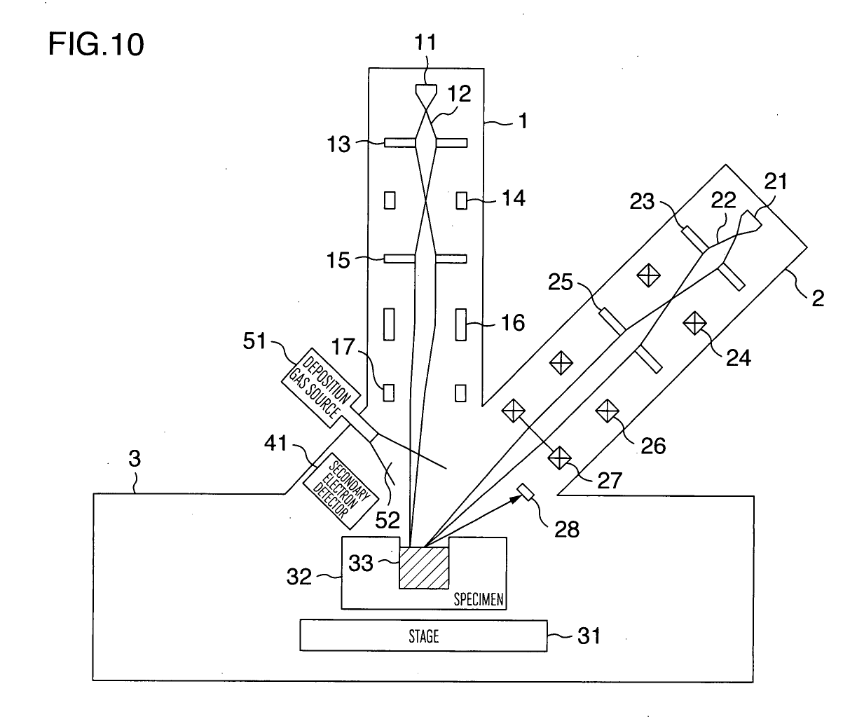

A fourth embodiment of the ion beam apparatus and analysis method according to the invention will be described with reference to FIG. 10. The ion beam apparatus according to the present embodiment differs from the first embodiment shown in FIG. 1 by additionally comprising an SEM column 2. The optical axis of SEM column 2 is tilted in relation to the normal of a specimen. In FIG. 10, illustration of the FIB column controller 18, overall controller 19, stage controller 34, deposition gas controller 53, height measurement controller 63, signal processor 42 and display unit 4 is omitted.

The SEM column 2 includes an electron source 21, an extraction electrode 23, a condenser lens 24, an aperture 25, a deflector 26, an objective lens 27 and a backscatter electron detector 28, having its interior maintained at high vacuum. Like the FIB column controller 18, an SEM column controller is provided for controlling the electron source 21, extraction electrode 23, condenser lens 24, aperture 25, deflector 26 and objective lens 27 but it is not illustrated herein.

In the present embodiment, an SIM image under irradiation of an ion beam 12 and an SEM (scanning electron microscope) image under irradiation of an electron beam 22 can both be obtained. Of these images, the SIM image can be obtained through the method which has already been described with reference to FIG. 1 and will not be described here and a method of obtaining an SEM image on the basis of the electron beam 22 will be described hereunder.

When a high voltage is applied to the electron source 21 and a voltage lower than the high voltage applied to the electron source 21 is applied to the extraction electrode 23, an electron beam 22 is emitted from the electron source 21. The electron beam 22 is converged by the condenser lens 24 so that the amount of electron beam passing through the aperture 25 may be adjusted. The electron beam 22 having passed through the aperture 25 is deflected by means of the deflector 26 and is then focused by means of the objective lens. The thus focused electron beam 22 is scanned on a specimen 32.

The backscatter electron detector 28 detects backscatter electrons generated from the specimen 32 irradiated with the electron beam 22. The signal processor 42 processes a backscatter electron detection signal from the backscatter electron detector 28 in synchronism with a scanning signal for electron beam deflection and delivers a resultant signal to the overall controller 19. The overall controller 19 displays an SEM image on the screen of display unit 4.

In the ion beam apparatus according to the present embodiment, an SEM image of the specimen 32 can be observed on real time base meanwhile the surface of specimen 32 being fabricated for boring or a deposition pile being formed by using an ion beam 12.

By changing the objective lens 27, the focal position of electron beam 22 is changed and differently focused SEM images can be obtained. When the scanning range of electron beam 22 is so set as to cover a position at which hole boring by the ion beam 12 proceeds and the objective lens 27 is controlled such that the SEM image is focused on the hole bottom, a depth of the hole can be determined from a focal distance at that time. Further, during hole filling after hole boring, too, information about the hole filling height can be monitored.

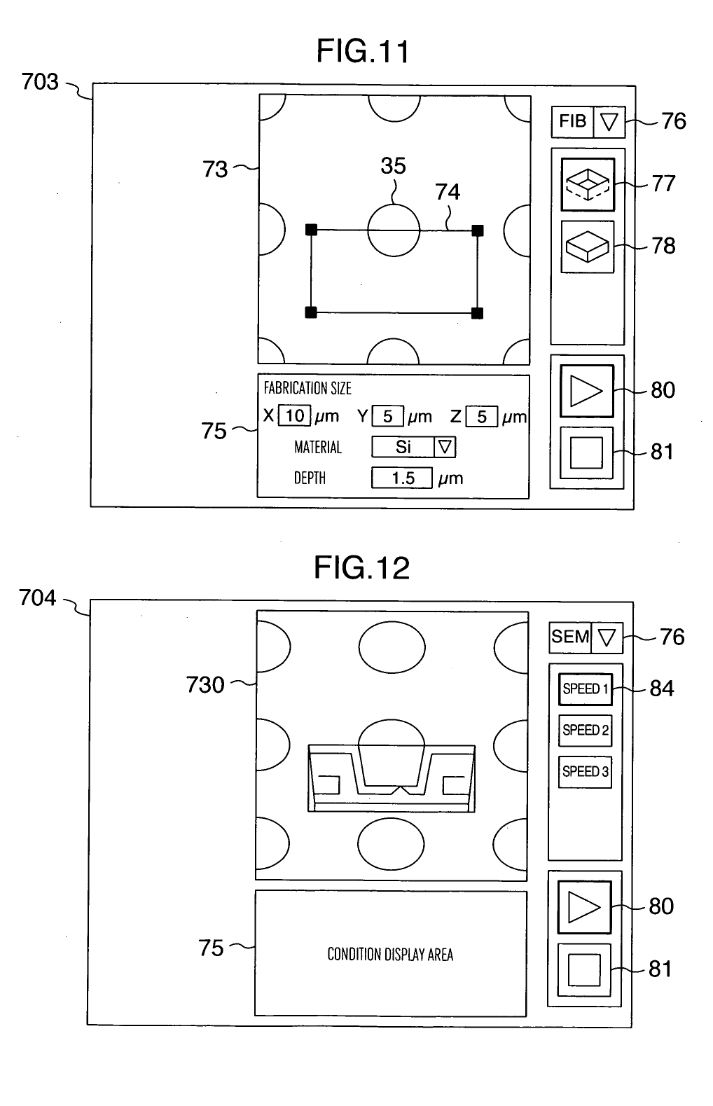

Turning to FIG. 11, an operation screen 703 displayed on the display unit 4 during hole boring fabrication will be described. The operation screen 703 includes an image display area 73, a condition display area 75, a selection button 76, a hole boring button 77, a deposition pile forming button 78, a start button 80 and a stop button 81. The operation screen 703 of the present embodiment differs from the operation screen 700 of FIG. 3 in that the selection button 76 is provided.

The selection button 76 is adapted to select either FIB or SEM. When the selection button 76 is clicked to select FIB and the hole boring button 77 is clicked, an SIM image of specimen 32 around a hole boring area is displayed together with a rubber band 74 for designating the hole boring area are displayed. Circular contact holes have already been formed in the specimen surface. The rubber band 74 is so set as to form a cross section of a contact hole. With the start button 80 clicked, the ion beam 12 is irradiated on an area on the surface of specimen 32 defined by the rubber band 74 and hole boring fabrication is started. Indicated in the condition display area 75 are a fabrication size, a material of the specimen and a depth. The fabrication size represents a geometrical dimension of the hole. The depth is one the hole has at present.

During hole boring fabrication, the electron beam 22 is irradiated onto a hole and the backscatter electron detector 28 detects a backscatter electron beam 22 from the hole. The position of objective lens 27 is controlled such that an SEM image of the hole can be in focus. In accordance with a controlled position of the objective lens 27, a depth of the hole, that is, a height of the deposition pile is measured. It is to be noted that the SEM image is not displayed on the operation screen 703. When the height of the deposition pile coincides with the height of peripheral edge of the hole, the hole filling fabrication ends.

Illustrated in FIG. 12 is an example of operation screen 704 displayed on the display unit 4 when the selection button 76 is clicked to select SEM. An SEM image is displayed in an image display area 730. A scanning speed setting button 84 is provided on the operation screen 704. A proper scanning speed is selected by means of the scanning speed setting button 84 and an SEM image of a bored cross section is displayed.

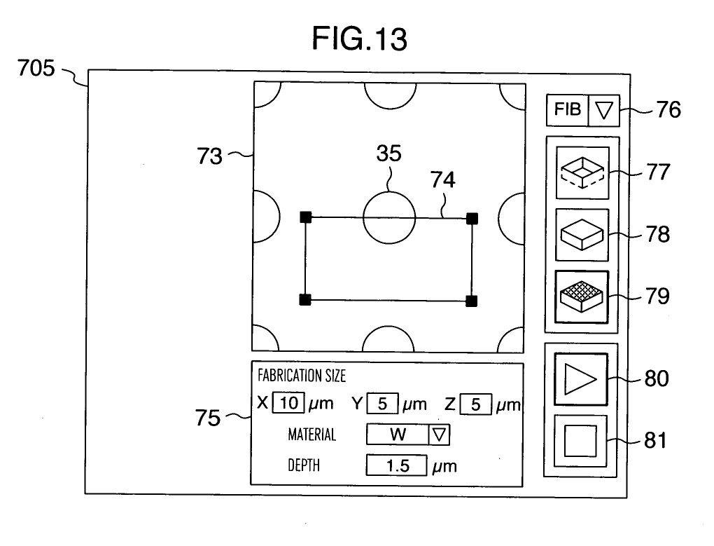

Illustrated in FIG. 13 is an operation screen 705 displayed on the display unit 4 when the selection button 76 is clicked to select FIB. By clicking the hole filling button 79, an SIM image around a hole and a rubber band 74 for designating a hole filling area are displayed in the image display area 73. A rectangular hole for exposing a cross section of a contact hole has already been formed in the surface of a specimen. The rubber band 74 is displayed at a position of the hole according to standards. The position of rubber band 74 can be changed through, for example, drag operation of a mouse. When the start button 80 is clicked, a deposition gas is supplied from the deposition gas source 51 and a deposition pile is formed in an area defined by the rubber band 74. In this manner, the hole is filled with the deposition pile.

Indicated in the condition display area 75 are a fabrication size, a material of the specimen and a depth. The fabrication size represents a geometrical dimension of the deposition pile and the depth is one the hole has at present. As the height of the hole coincides with that of the peripheral edge of the hole, the hole filling fabrication ends.

### Embodiment 5

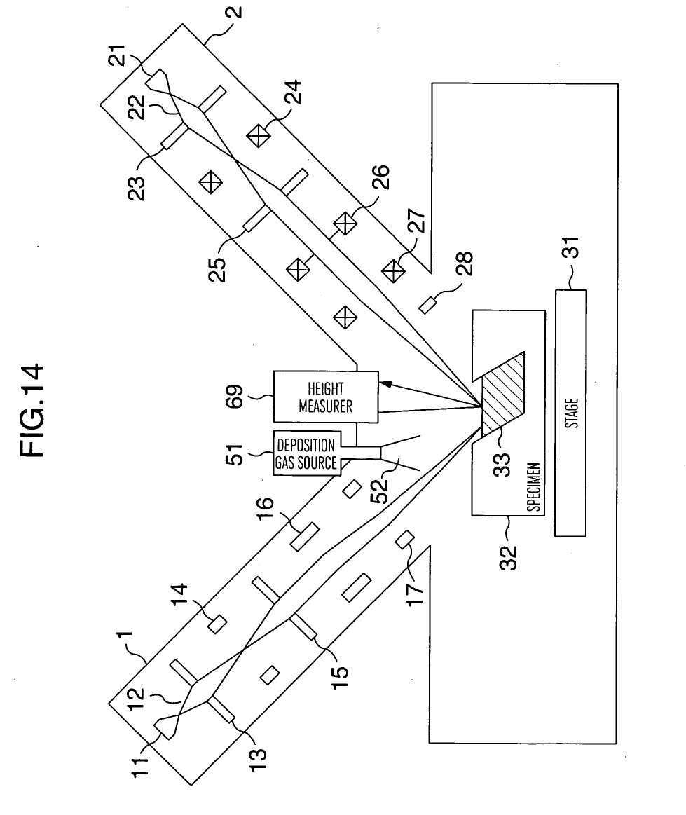

Referring to FIG. 14, there is illustrated a fifth embodiment of the ion beam apparatus according to the invention. The ion beam apparatus of the present embodiment differs from the fourth embodiment of FIG. 10 in that the optical axis of an FIB column 1 and that of an SEM column 2 are both tilted in relation to the normal of a specimen. In the present embodiment, a hole tilted in depth direction can be bored in the surface of the specimen and the hole tilted in depth direction can be filled with a deposition pile.

A height measurer 69 is arranged above a specimen 32. The height measure 69 has a laser beam source and a laser beam detector. Accordingly, in the height measurer 69 of the present embodiment, the height measurer (on laser beam source side) and height measurer (on laser beam detector side) which have been set forth so far are integrated and a single connection port to the specimen chamber suffices. With the height measurer 69 arranged above the specimen 32, a depth of the hole tilted in depth direction can be measured and a height of a deposition pile for filling the hole tilted in depth direction can be measured.

In FIG. 14, illustration of the FIB column controller 18, overall controller 19, stage controller 34, deposition gas controller 53, height measurement controller 63, signal processor 42 and display unit 4 is omitted.

According to the present invention, since precise deposition can be performed while measuring the height of the deposition pile, not only hole filling but also correction of wiring for connecting circuits with a conductive deposition pile in a semiconductor device can be carried out. Namely, in the wiring correction or modification of circuits in the semiconductor device, the present invention can also be applied to utilization of wiring with correct resistance values.

While the present invention has been described by way of example, the invention is by no means limited to the foregoing embodiments and persons skilled in the art should understand that various changes, alterations and modifications can be made within the framework of the invention recited in the appended scope of claim for a patent.

1. An ion beam apparatus comprising:
an ion beam illuminating system for irradiating a scanning ion beam on a specimen;
a deposition gas source for supplying a deposition gas; and
a measuring instrument for measuring a depth of a hole bored in the surface of the specimen or a height of a deposition pile formed in said hole,
wherein when a deposition pile is formed in a hole bored in the specimen surface, the depth of the hole in the specimen surface or the height of the deposition pile formed in said hole and then formation of said deposition pile is stopped.

2. An ion beam apparatus according to claim 1, wherein the formation of said deposition pile is stopped when it is determined that the height of said deposition pile substantially coincides with the height of the peripheral edge of said hole.

3. An ion beam apparatus according to claim 1, wherein said deposition pile is formed such that an unevenness of the specimen surface comes to 50 nm or less.

4. An ion beam apparatus according to claim 1, wherein said measuring instrument includes a laser beam source for irradiating a laser beam onto said deposition pile and a laser beam detector for detecting a laser beam from a laser beam irradiation area.

5. An ion beam apparatus according to claim 4, wherein said laser beam source irradiates a laser beam having a beam spot larger than said hole bored in the specimen surface and said laser beam detector measures from a quantity of a beam detected thereby a depth of said hole or a height of said deposition pile.

6. An ion beam apparatus according to claim 4, wherein said laser beam source irradiates a laser beam having a beam spot smaller than said hole bored in the specimen surface and said laser beam detector measures from a position of a beam detected thereby a depth of said hole or a height of said deposition pile.

7. An ion beam apparatus according to claim 1, wherein said laser beam source irradiates either a laser beam of large beam spot or a laser beam of small beam spot and wherein when said laser beam source irradiates the laser beam of large beam spot, said laser beam detector measures from a quantity of a beam detected thereby a depth of said hole or a height of said deposition pile and when said laser beam source irradiates the laser beam of small beam spot, said laser beam detector measures from a position of a beam detected thereby a depth of said hole or a height of said deposition pile.

8. An ion beam apparatus according to claim 1, wherein said measuring instrument includes an electron beam illuminating system for irradiating a scanning electron beam on the specimen, a backscatter electron detector for detecting a backscatter electron beam from an electron beam irradiation area and a scanning electron microscope for generating an SEM image on the basis of a signal from said backscatter electron detector.

9. An ion beam apparatus according to claim 1, wherein when, during boring a hole in said specimen surface, it is determined through measurement by said measuring instrument that the hole depth comes to a predetermined depth, the hole boring is stopped.

10. An ion beam apparatus comprising:
an ion beam illuminating system for irradiating a scanning ion beam on a specimen;
a secondary electron detector for detecting a secondary electron beam from an ion beam irradiation area;
a display unit for displaying an SEM image generated on the basis of a signal from said secondary electron detector;
a deposition gas source for supplying a deposition gas; and
a measuring instrument for measuring a depth of a hole bored in the specimen surface or a height of a deposition pile formed in said hole,
wherein while said deposition pile being formed in said hole bored in the specimen surface, said display unit displays an SIM image of an area encompassing said hole bored in the specimen surface and a height, measured by said measuring instrument, of said deposition pile formed in said hole bored in the specimen surface.

11. An ion beam apparatus according to claim 10, wherein said measuring instrument has a laser beam source for irradiating a laser beam on said deposition pile and a laser beam detector for detecting a laser beam from a laser beam irradiation area and said laser beam detector measures a depth of said hole bored in the specimen surface or a height of said deposition pile formed in said hole on the basis of a quantity of a beam detected by said laser beam detector or a position of a beam detected thereby.

12. An ion beam apparatus according to claim 10, wherein, during boring said hole in the specimen surface, said display unit displays an SIM image of an area encompassing said hole bored in the specimen surface and the depth of said hole in the specimen surface measured by said measuring instrument.

13. An ion beam apparatus according to claim 10, wherein said measuring instrument includes an electron beam illuminating system for irradiating a scanning electron beam on the specimen, a backscatter electron detector for detecting a backscatter electron beam from an electron beam irradiation area and a scanning electron microscope for generating an SEM image on the basis of a signal from said backscatter electron detector, said display unit functioning to display the SEM image generated by said scanning electron microscope.

14. An ion beam apparatus according to claim 13, wherein said display unit performs switchover display between an SIM image and an SEM image of an area encompassing said deposition pile.

15. An ion beam apparatus according to claim 10, wherein said display unit displays an operation screen for either hole boring fabrication or hole filling fabrication, said operation screen includes an image display area, a condition display area, a hole boring button and a hole filling button and wherein an SIM of the specimen surface and a rubber band for designating a fabrication area are displayed in said image display area.

16. An ion beam apparatus according to claim 15, wherein a fabrication size, a material and a depth of said hole or a height of said deposition pile are indicated in said condition display area.

17. An ion beam analysis method comprising the steps of:
forming a deposition pile by irradiating an ion beam in a hole bored in the surface of a specimen while supplying a deposition gas in vacuum;
measuring a height of said deposition pile formed in said hole; and
stopping the supply of deposition gas and the irradiation of ion beam when the height of said deposition pile equals the height of the peripheral edge of said hole.

18. An ion beam analysis method according to claim 17, wherein during formation of said deposition pile, an SIM image of an area encompassing said hole and the height of said deposition pile are displayed on a display unit.

19. An ion beam analysis method according to claim 17, wherein during formation of said deposition pile, said display unit performs switchover display between an SIM image and an SEM image of an area encompassing said hole.

20. An ion beam analysis method according to claim 17, wherein measurement of said deposition pile includes the steps of:
irradiating a laser beam on said deposition pile;
detecting a laser beam from a laser beam irradiation area; and
determining a height of said deposition pile from a quantity or position of a detected laser beam.

21. An ion beam analysis method comprising the steps of:
boring a hole by irradiating an ion beam on the surface of a specimen in vacuum;
measuring a depth of said hole; and
stopping irradiation of said ion beam when the depth of said hole comes to a predetermined value.

22. An ion beam analysis method according to claim 21 further comprising a step of displaying an SIM image of an area encompassing said hole and a height of said deposition pile on a display unit during formation of said deposition pile.
